(19) United States
(12) Patent Application Publication
(10) Pub. No.: US 2023/0092110 A1
(43) Pub. Date: Mar. 23, 2023

(54) POWER CONVERTER, MOTOR DRIVE CONTROLLER, BLOWER, COMPRESSOR, AND AIR CONDITIONER

(71) Applicant: Mitsubishi Electric Corporation, Tokyo (JP)

(72) Inventors: Satoru ICHIKI, Tokyo (JP); Koichi ARISAWA, Tokyo (JP); Kazunori HATAKEYAMA, Tokyo (JP); Takahiko KOBAYASHI, Tokyo (JP)

(21) Appl. No.: 17/800,444

(22) PCT Filed: Apr. 25, 2020
(86) PCT No.: PCT/JP2020/017873

§ 371 Date: Aug. 17, 2022

(51) Int. Cl. H02P 27/06; F24F 11/88; H01L 25/16; H01L 23/00; H01L 23/367; H01L 23/498; H02M 3/156

(52) U.S. Cl. CPC H02P 27/06; F24F 11/88; H01L 25/16; H01L 24/48; H01L 23/3672; H01L 23/49827; H02M 3/156; H01L 2224/48137; H01L 2224/48195; H01L 2224/48227; H01L 2924/10254; H01L 2924/10272; H01L 2924/1033; H01L 2924/1203; H01L 2924/13055; H01L 2924/19042; H01L 2924/19105; H02P 2201/09

(57) ABSTRACT

A power converter for converting a voltage of direct-current power output from a direct-current power supply, the power converter including: a printed circuit board; a reactor being configured with a conductor pattern of the printed circuit board; a semiconductor element that is connected to another end of the reactor and performs switching for storing electrical energy in the reactor so as to boost the voltage of the direct-current power from a first voltage to a second voltage; a capacitor that smooths the direct-current power boosted to the second voltage; a diode that is connected to the another end of the reactor and supplies the direct-current power boosted to the second voltage to the capacitor; and a cooler, wherein the reactor, the semiconductor element, and the diode are included in a module in a single package, and the module is cooled by the cooler.

### CROSS REFERENCE TO RELATED APPLICATION

This application is a U.S. National Stage Application of International Patent No. PCT/JP2020/017873 filed on Apr. 25, 2020, the disclosure of which is incorporated herein by reference.

### TECHNICAL FIELD

The present disclosure relates to a power converter that converts the voltage of direct-current power, a motor drive controller, a blower, a compressor, and an air conditioner.

### BACKGROUND

Conventionally, an insulated gate bipolar transistor (IGBT) using silicon (Si) is mainly applied as a power semiconductor module in a power converter. However, in recent years, wide bandgap semiconductors such as silicon carbide (SiC) and gallium nitride (GaN) have been attracting attention as semiconductor elements to be used for power semiconductor modules. A wide bandgap semiconductor has a switching speed faster than that of silicon (Si). Accordingly, a wide bandgap semiconductor has a lower loss at the time of switching, so that switching can be performed at high frequency. Therefore, in recent years, a study of a module using a wide bandgap semiconductor has been in progress.

A boost chopper circuit performs switching at high frequency by using a wide bandgap semiconductor, so that a boost reactor can be downsized. However, since the boost chopper circuit using a wide bandgap semiconductor performs switching at high speed, a phenomenon called ringing is caused by LC resonance due to parasitic capacitance of elements included in a module and parasitic inductance generated between a reactor and a switching element. The ringing occurs during operation of the switching element in the module.

If the peak value of voltage exceeds the rated voltage of the module due to ringing, it may cause breakage of the module. In order to address such a problem, Patent Literature 1 discloses a technique in which, as countermeasures against ringing, a power converter includes a snubber circuit in parallel with a switching element in a module so as to suppress a voltage peak from increasing due to ringing.

### PATENT LITERATURE

Patent Literature 1: Japanese Patent No. 6513303

However, in the power converter described in Patent Literature 1, a loss is produced in the snubber circuit, and in addition, the snubber circuit needs to be cooled. Therefore, the power converter described in Patent Literature 1 has a problem in that cost increases due to an increase in size of the apparatus, and the cooling surface of the module increases.

### SUMMARY

The present disclosure has been made in view of the above, and an object of the present disclosure is to obtain a power converter capable of suppressing the occurrence of ringing while suppressing an increase in size of the apparatus.

To solve the above problems and achieve the object the present disclosure relates to a power converter adapted to convert a voltage of direct-current power output from a direct-current power supply. The power converter includes: a circuit board; a reactor having one end connected to the direct-current power supply, the reactor being configured with a conductor pattern of the circuit board; a semiconductor element connected to another end of the reactor and adapted to perform switching for storing electrical energy in the reactor so as to boost the voltage of the direct-current power from a first voltage to a second voltage; a capacitor adapted to smooth the direct-current power boosted to the second voltage; a diode connected to the another end of the reactor and adapted to supply the direct-current power, boosted to the second voltage, to the capacitor; and a cooler. The reactor, the semiconductor element, and the diode are included in a module in a single package, and the module is cooled by the cooler.

The power converter according to the present disclosure has the effect of suppressing the occurrence of ringing while suppressing an increase in size of the apparatus.

### BRIEF DESCRIPTION OF DRAWINGS

FIG. 1 is a diagram showing an example of a circuit configuration of a power converter according to a first embodiment.

FIG. 2 is a first perspective view of an internal configuration of a module included in the power converter according to the first embodiment.

FIG. 3 is a schematic diagram illustrating a cross-sectional structure of the module included in the power converter according to the first embodiment.

FIG. 4 is a second perspective view of the internal configuration of the module included in the power converter according to the first embodiment.

FIG. 5 is a perspective view of an internal configuration of a module included in a power converter according to a second embodiment.

FIG. 6 is a schematic diagram illustrating a cross-sectional structure of the module included in the power converter according to the second embodiment.

FIG. 7 is a diagram illustrating an exemplary configuration of a motor drive controller according to a third embodiment.

FIG. 8 is a diagram illustrating an exemplary configuration of a blower including the motor drive controller according to the third embodiment.

FIG. 9 is a diagram illustrating an exemplary configuration of a compressor including the motor drive controller according to the third embodiment.

FIG. 10 is a diagram illustrating an exemplary configuration of an air conditioner including the motor drive controller according to the third embodiment.

### DETAILED DESCRIPTION

Hereinafter, a power converter, a motor drive controller, a blower, a compressor, and an air conditioner according to embodiments of the present disclosure will be described in detail with reference to the drawings.

### First Embodiment

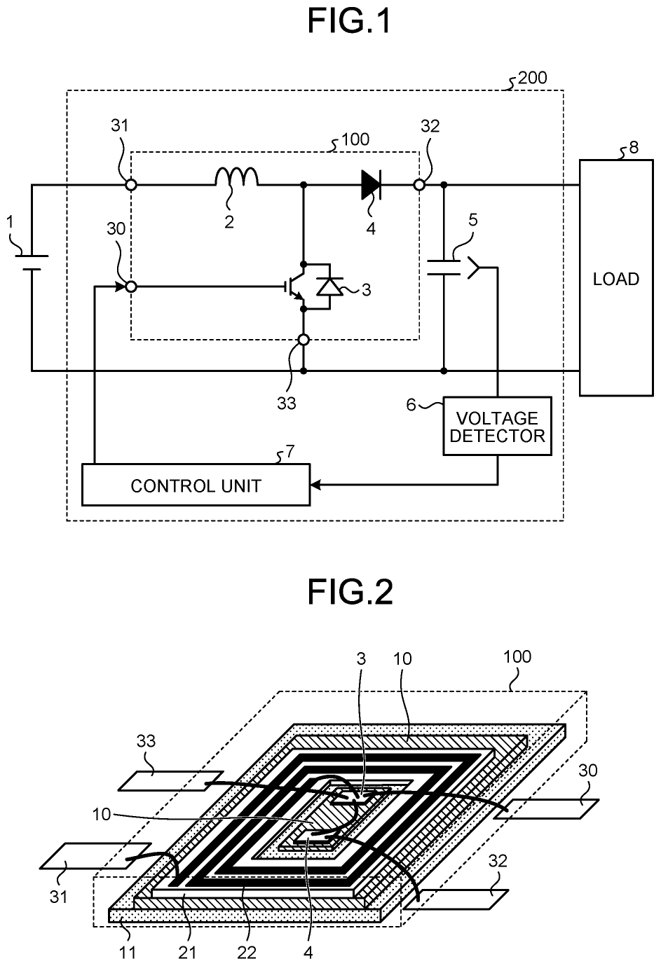

FIG. 1 is a diagram showing an example of a circuit configuration of a power converter 200 according to a first embodiment. The power converter 200 is connected to a direct-current power supply 1 and a load 8. The power converter 200 converts, specifically, boosts a voltage of direct-current power output from the direct-current power supply 1, and outputs the voltage to the load 8. The power supply connected to the power converter 200 is not limited to the direct-current power supply 1, and may be an alternating-current power supply. In a case where the power supply connected to the power converter 200 is an alternating-current power supply, the power converter 200 just needs to include a rectifier circuit such as a diode bridge and convert alternating-current power output from the alternating-current power supply into direct-current power. A configuration of the power converter 200 will be described. The power converter 200 includes a reactor 2, a semiconductor element 3, a diode 4, a capacitor 5, a voltage detector 6, and a control unit 7.

The reactor 2 has one end connected to the high-voltage side of the direct-current power supply 1, and has another end connected to one end of the semiconductor element 3 and one end of the diode 4.

The one end of the semiconductor element 3 is connected to the another end of the reactor 2 and the one end of the diode 4; and another end of the semiconductor element 3 is connected to the low-voltage side of the direct-current power supply 1 and another end of the capacitor 5. The semiconductor element 3 performs switching for storing electrical energy in the reactor 2 so as to boost the voltage of direct-current power output from the direct-current power supply 1 from a first voltage to a second voltage. The semiconductor element 3 performs switching in accordance with a control signal received from the control unit 7, that is, under the control of the control unit 7.

Here, a switching element using a wide bandgap semiconductor typified by silicon carbide (SiC), gallium nitride (GaN), and diamond (C) is used as the semiconductor element 3. That is, the semiconductor element 3 is formed of a wide bandgap semiconductor. Not only a metal-oxide-semiconductor field-effect transistor (MOSFET) but also a super junction MOSFET or the like is used as the semiconductor element 3.

The one end of the diode 4 is connected to the another end of the reactor 2 and the one end of the semiconductor element 3; and another end of the diode 4 is connected to one end of the capacitor 5. The diode 4 supplies the capacitor 5 with direct-current power boosted to the second voltage.

The one end of the capacitor 5 is connected to the another end of the diode 4. The another end of the capacitor 5 is connected to the low-voltage side of the direct-current power supply 1 and the another end of the semiconductor element 3. The capacitor 5 is an electrolytic capacitor that smooths the direct-current power boosted to the second voltage.

The voltage detector 6 detects a voltage between both ends of the capacitor 5. The voltage detector 6 outputs a voltage value of the detected voltage between both ends of the capacitor 5 to the control unit 7.

The control unit 7 controls the switching of the semiconductor element 3 by using the voltage value detected by the voltage detector 6. Specifically, by using the voltage value detected by the voltage detector 6, the control unit 7 generates a control signal for causing the semiconductor element 3 to operate. The control unit 7 outputs the generated control signal to the semiconductor element 3.

In the first embodiment, the reactor 2, the semiconductor element 3, and the diode 4 are included in a module 100 molded in a single package. That is, the power converter 200 includes the module 100 that includes the reactor 2, the semiconductor element 3, and the diode 4 included in the single package.

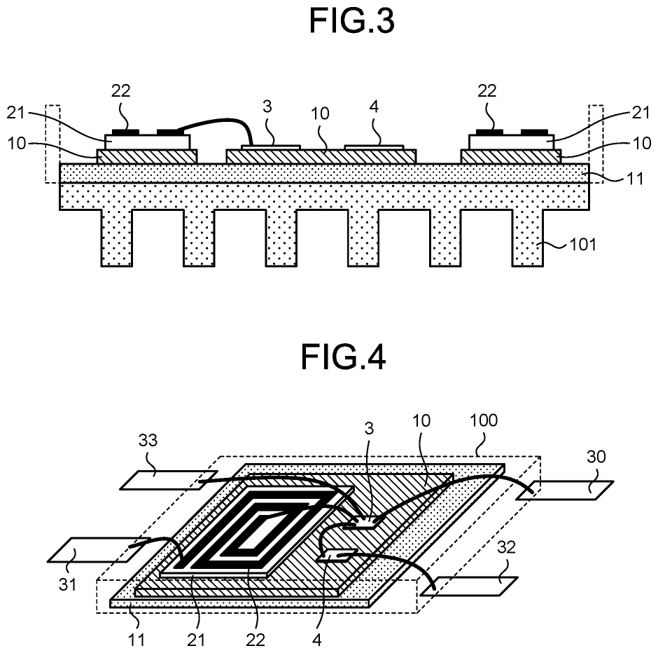

FIG. 2 is a first perspective view of an internal configuration of the module 100 included in the power converter 200 according to the first embodiment. FIG. 3 is a schematic diagram illustrating a cross-sectional structure of the module 100 included in the power converter 200 according to the first embodiment. In the first embodiment, the power converter 200 includes a cooler 101 for cooling the module 100. In addition, the module 100 includes a metal plate 11 and a printed circuit board 21. As illustrated in FIGS. 2 and 3, the reactor 2 is configured with a conductor pattern 22 that is a spiral-shaped pattern on the printed circuit board 21 that is a circuit board. The reactor 2 is disposed in such a way as to surround the semiconductor element 3 and the diode 4. The reactor 2 is mounted on the metal plate 11 via an insulator 10. The semiconductor element 3 and the diode 4 are mounted on the metal plate 11 via the insulator 10.

The module 100 is in contact with the cooler 101 via a second surface opposite to a first surface of the metal plate 11 on which the reactor 2, the semiconductor element 3, and the diode 4 are mounted via the insulators 10. The module 100 is cooled by the cooler 101.

The module 100 includes four terminals 30 to 33 for connecting with the outside. The terminal 30 is a control terminal that acquires a control signal from the control unit 7 and outputs the control signal to the semiconductor element 3. The terminal 31 is a terminal for connecting the one end of the reactor 2 to the high-voltage side of the direct-current power supply 1. The terminal 32 is a terminal for connecting the another end of the diode 4 to the one end of the capacitor 5. The terminal 33 is a terminal for connecting the another end of the semiconductor element 3 to the low-voltage side of the direct-current power supply 1.

Note that the printed circuit board 21 may be configured such that the conductor pattern 22 can be provided only in a single layer of the surface, or may be formed as a multilayer wiring board configured such that a plurality of layers are provided therein and the conductor pattern 22 can be provided in each layer. In addition, the reactor 2 may be mounted on an insulator and a metal plate different from the insulator 10 and the metal plate 11.

In the module 100, a resin member surrounding the semiconductor element 3, the diode 4, and the like is bonded with adhesive. The inside of the module 100 is sealed with a gel-like sealing material. In the module 100, the semiconductor element 3 and at least a part of the diode 4 are sealed with the sealing material. Note that the module 100 may be sealed with, for example, resin molded by a transfer molding method.

In addition, the internal configuration of the module 100 is not limited to the configuration in which the reactor 2 is disposed around the semiconductor element 3 and the diode 4 as illustrated in FIG. 2. FIG. 4 is a second perspective view of the internal configuration of the module 100 included in the power converter 200 according to the first embodiment. The module 100 may be configured such that, for example, the reactor 2 is disposed beside the semiconductor element 3 and the diode 4 as illustrated in FIG. 4.

Furthermore, in the first embodiment, the module 100 includes two elements namely the semiconductor element 3 and the diode 4, but this is an example, and the configuration of the module 100 is not limited thereto. The module 100 may be configured such that a plurality of booster circuits each including the reactor 2, the semiconductor element 3, and the diode 4 are placed in parallel. That is, the module 100 may include a plurality of the semiconductor elements 3 and a plurality of the diodes 4. In this case, at least one of the plurality of semiconductor elements 3 included in the module 100 may be formed of a wide bandgap semiconductor.

As described above, according to the first embodiment, the power converter 200 includes the module 100 in which the reactor 2 is configured with the conductor pattern 22 of the printed circuit board 21, and the reactor 2, the semiconductor element 3, and the diode 4 are housed in a single package. Therefore, in the power converter 200, a wire connecting the reactor 2 with the semiconductor element 3 can be shortened. As a result, the power converter 200 can reduce parasitic inductance to be generated between the reactor 2 and the semiconductor element 3 and suppress ringing from being caused by LC resonance due to the parasitic inductance and parasitic capacitance of the element. Furthermore, in the power converter 200, it is possible to further shorten: a wire connecting the terminal 31 with the reactor 2; and the wire connecting the reactor 2 with the semiconductor element 3, by disposing the reactor 2 in such a way as to surround the semiconductor element 3 and the diode 4.

Moreover, in the power converter 200, the reactor 2, the semiconductor element 3, and the diode 4 are mounted on the metal plate 11 via the insulators 10. As a result, in the power converter 200, it is possible to cool the reactor 2 together with the semiconductor element 3 and the diode 4 by means of the cooler 101, so that a cooling structure can be downsized. Since the power converter 200 can downsize the cooling structure, it is possible to suppress an increase in size of the apparatus and to reduce cost.

### Second Embodiment

In a second embodiment, a case where the module 100 of the power converter 200 includes no metal plate 11 will be described.

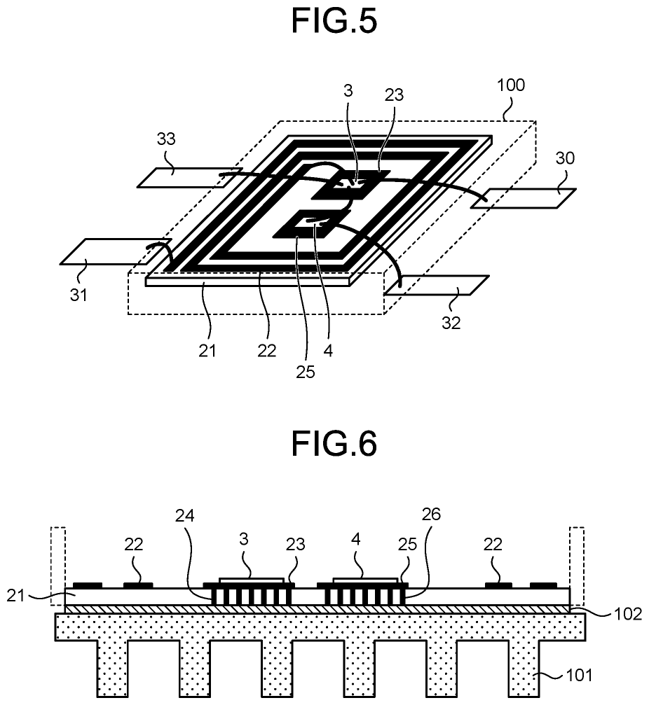

In the second embodiment, a circuit configuration of the power converter 200 is the same as the circuit configuration of the power converter 200 of the first embodiment illustrated in FIG. 1. FIG. 5 is a perspective view of an internal configuration of the module 100 included in the power converter 200 according to the second embodiment. FIG. 6 is a schematic diagram illustrating a cross-sectional structure of the module 100 included in the power converter 200 according to the second embodiment. In the second embodiment, the power converter 200 includes a cooler 101 for cooling the module 100. In addition, the module 100 includes the printed circuit board 21. As illustrated in FIGS. 5 and 6, the reactor 2 is configured with the conductor pattern 22 that is a spiral-shaped pattern on the printed circuit board 21 that is a circuit board. The reactor 2 is disposed in such a way as to surround the semiconductor element 3 and the diode 4. The reactor 2 is mounted on the printed circuit board 21

In the second embodiment, a first surface of the printed circuit board 21 is defined as a surface on which the reactor 2 is configured with the conductor pattern 22, and a second surface of the printed circuit board 21 is defined as a surface opposite to the first surface. In the following description, the conductor pattern 22 may be referred to as a first conductor pattern. The semiconductor element 3 is mounted on a conductor pattern 23 insulated from the conductor pattern 22 on the first surface of the printed circuit board 21. The conductor pattern 23 is connected to the second surface of the printed circuit board 21 via through-holes 24. In the following description, the conductor pattern 23 may be referred to as a second conductor pattern. The diode 4 is mounted on a conductor pattern 25 insulated from the conductor pattern 22 and the conductor pattern 23 on the first surface of the printed circuit board 21. The conductor pattern 25 is connected to the second surface of the printed circuit board 21 via through-holes 26. In the following description, the conductor pattern 25 may be referred to as a third conductor pattern. The conductor patterns 22, 23, and 25 are conductor patterns that are not electrically connected to each other.

The module 100 is in contact with the cooler 101 via: the second surface of the printed circuit board 21, on which the reactor 2, the semiconductor element 3, and the diode 4 are not mounted; and an insulator 102. The module 100 is cooled by the cooler 101.

Similarly to the first embodiment, the printed circuit board 21 may be configured such that the conductor patterns 22, 23, and 25 can be provided only in a single layer of the surface, or may be formed as a multilayer wiring board configured such that a plurality of layers is provided therein and the conductor patterns 22, 23, and 25 can be provided in each layer.

In the module 100, a resin member surrounding the semiconductor element 3, the diode 4, and the like is bonded with adhesive. The inside of the module 100 is sealed with a gel-like sealing material. In the module 100, the semiconductor element 3 and at least a part of the diode 4 are sealed with the sealing material. Note that the module 100 may be sealed with, for example, resin molded by a transfer molding method.

In addition, the internal configuration of the module 100 is not limited to the configuration in which the reactor 2 is disposed around the semiconductor element 3 and the diode 4 as illustrated in FIG. 5. Although not illustrated, the module 100 may be configured such that, for example, the reactor 2 is disposed beside the semiconductor element 3 and the diode 4 as illustrated in FIG. 4 provided for comparison with FIG. 2 illustrating the internal configuration of the module 100 of the first embodiment.

Furthermore, in the second embodiment, the module 100 includes two elements namely the semiconductor element 3 and the diode 4, but this is an example, and the configuration of the module 100 is not limited thereto. The module 100 may be configured such that a plurality of booster circuits each including the reactor 2, the semiconductor element 3, and the diode 4 are placed in parallel. That is, the module 100 may include a plurality of the semiconductor elements 3 and a plurality of the diodes 4. In this case, at least one of the plurality of semiconductor elements 3 included in the module 100 may be formed of a wide bandgap semiconductor.

As described above, in the power converter 200 according to the second embodiment, the printed circuit board 21 on which the reactor 2 is configured with the conductor pattern 22 can be directly attached to the cooler 101 located outside. In addition, the power converter 200: can dissipate heat generated by the semiconductor element 3 to the cooler 101 through the through-holes 24 provided in the printed circuit board 21; and can dissipate heat generated by the diode 4 to the cooler 101 through the through-holes 26 provided in the printed circuit board 21. As a result, since the metal plate 11 can be omitted in the power converter 200, the number of parts can be reduced to achieve a simple configuration, and the cost of the module 100 can be reduced as compared with the first embodiment. Furthermore, in the power converter 200 of the second embodiment, the cooler 101 can be downsized, and the cost of the cooler 101 can be reduced. Moreover, in the power converter 200 of the second embodiment, the printed circuit board 21 can be brought into contact with the cooler 101 via the insulator 102, so that cooling effect can be improved as compared with the first embodiment.

### Third Embodiment

In a third embodiment, a description will be given of a case where the power converter 200 described in the first embodiment and the second embodiment is applied to a motor drive controller that supplies direct-current power to an inverter to drive a motor.

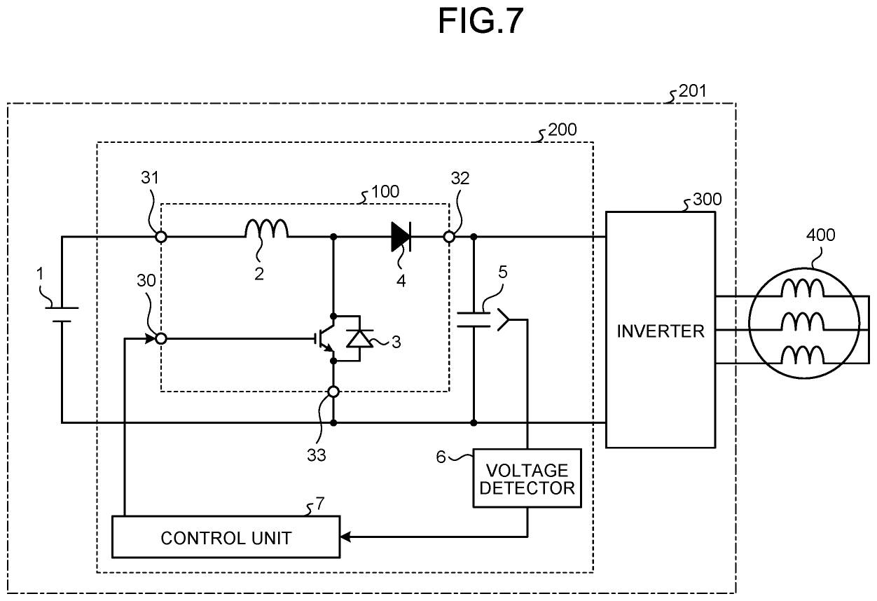

FIG. 7 is a diagram illustrating an exemplary configuration of a motor drive controller 201 according to the third embodiment. The motor drive controller 201 includes the power converter 200 and an inverter 300. The inverter 300 corresponds to the load 8 illustrated in FIG. 1, and converts direct-current power output from the power converter 200 into alternating-current power. A motor 400 is connected to the output side of the inverter 300. The inverter 300 drives the motor 400 by supplying the converted alternating-current power to the motor 400. The motor drive controller 201 illustrated in FIG. 7 can be applied to products such as a blower, a compressor, and an air conditioner.

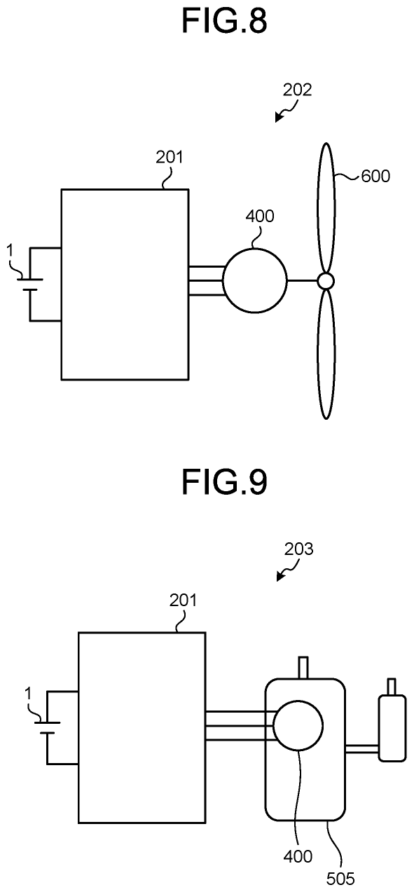

FIG. 8 is a diagram illustrating an exemplary configuration of a blower 202 including the motor drive controller 201 according to the third embodiment. The blower 202 includes the motor drive controller 201. The blower 202 can rotate a fan 600 by causing the motor drive controller 201 to drive the motor 400.

FIG. 9 is a diagram illustrating an exemplary configuration of a compressor 203 including the motor drive controller 201 according to the third embodiment. The compressor 203 includes the motor drive controller 201. The compressor 203 can compress a refrigerant in a compression unit 505 by causing the motor drive 201 to drive the motor 400.

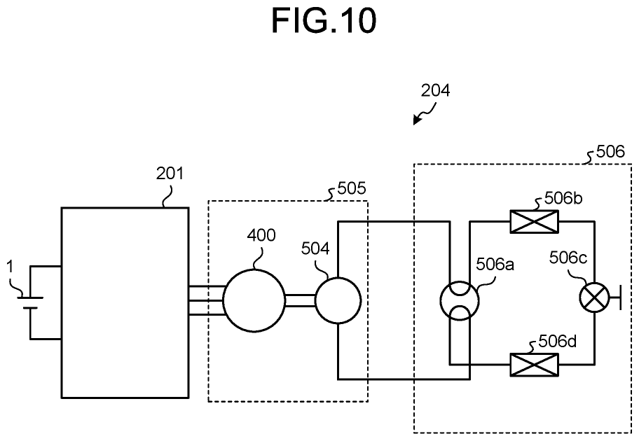

FIG. 10 is a diagram illustrating an exemplary configuration of an air conditioner 204 including the motor drive controller 201 according to the third embodiment. The air conditioner 204 includes the motor drive controller 201. The air conditioner 204 may include at least one of the blower 202 illustrated in FIG. 8 and the compressor 203 illustrated in FIG. 9. In the air conditioner 204, the motor 400 is connected to the motor drive controller 201. The motor 400 is coupled to a compression element 504. The compression unit 505 includes the motor 400 and the compression element 504. A refrigeration cycle unit 506 includes a four-way valve 506a, an indoor heat exchanger 506b, an expansion valve 506c, and an outdoor heat exchanger 506d.

The flow path of a refrigerant circulating in the air conditioner 204 is formed such that the refrigerant flows from the compression element 504 through the four-way valve 506a, the indoor heat exchanger 506b, the expansion valve 506c, and the outdoor heat exchanger 506d, and then flows through the four-way valve 506a again to return to the compression element 504. The motor drive controller 201 receives direct-current power supplied from the direct-current power supply 1, converts the direct-current power into alternating-current power, and rotates the motor 400. As the motor 400 rotates, the compression element 504 performs operation of compressing the refrigerant, so that the refrigerant can be circulated inside the refrigeration cycle unit 506.

As described above, according to the third embodiment, the power converter 200 can be applied to the motor drive controller 201. Furthermore, the motor drive controller 201 can be applied to products such as the blower 202, the compressor 203, and the air conditioner 204. As a result, the effect described in the first embodiment or the second embodiment can be enjoyed in products such as the blower 202, the compressor 203, and the air conditioner 204.

The configurations set forth in the above embodiments show examples, and it is possible to combine the configurations with another known technique or combine the embodiments with each other, and is also possible to partially omit or change the configurations without departing from the scope of the present disclosure.

1. A power converter adapted to convert a voltage of direct-current power output from a direct-current power supply, the power converter comprising:
a circuit board;
a reactor having one end connected to the direct-current power supply, the reactor being configured with a conductor pattern of the circuit board;
a semiconductor element connected to another end of the reactor and adapted to perform switching for storing electrical energy in the reactor so as to boost the voltage of the direct-current power from a first voltage to a second voltage;
a capacitor adapted to smooth the direct-current power boosted to the second voltage;
a diode connected to the another end of the reactor and adapted to supply the direct-current power, boosted to the second voltage, to the capacitor; and
a cooler, wherein
the reactor, the semiconductor element, and the diode are included in a module in a single package, and
the module is cooled by the cooler, wherein
the reactor is disposed in such a way as to surround the semiconductor element and the diode.

2. The power converter according to claim 1, comprising:
a metal plate on which the reactor, the semiconductor element, and the diode are mounted via an insulator in the module, wherein
the module is in contact with the cooler via a second surface of the metal plate, the second surface being a surface opposite to a first surface on which the reactor, the semiconductor element, and the diode are mounted via the insulator.

3. The power converter according to claim 1, wherein
the semiconductor element is mounted on a second conductor pattern on a first surface of the circuit board, and
the diode is mounted on a third conductor pattern on the first surface, wherein
the reactor is configured with a first conductor pattern on the first surface;
the first conductor pattern is the conductor pattern of the circuit board;
the second conductor pattern is insulated from the first conductor pattern; and
the third conductor pattern is insulated from the first conductor pattern and the second conductor pattern.

4. The power converter according to claim 3, wherein
the second conductor pattern and the third conductor pattern are connected to a second surface of the circuit board via through-holes, wherein
the second surface is a surface opposite to the first surface, and
the module is in contact with the cooler via the second surface of the circuit board and an insulator.

5. (canceled)

6. The power converter according to claim 1,
wherein
the module is configured such that a plurality of booster circuits each including the reactor, the semiconductor element, and the diode are placed in parallel, wherein
at least one of the semiconductor elements is formed of a wide bandgap semiconductor.

7. The power converter according to claim 6, wherein
the wide bandgap semiconductor is silicon carbide, gallium nitride, or diamond.

8. A motor drive controller comprising:
the power converter according to claim 1; and
an inverter adapted to convert direct-current power output from the power converter into alternating-current power.

9. A blower comprising the motor drive controller according to claim 8.

10. A compressor comprising the motor drive controller according to claim 8.

11. An air conditioner comprising the blower according to claim 9.

12. An air conditioner comprising the compressor according to claim 10.
